(19) United States
(12) Patent Application Publication
(10) Pub. No.: US 2003/0095675 A1
(43) Pub. Date: May 22, 2003

(54) Light communication channel-based voice-activated control system and method for implementing thereof

(76) Inventors: C. Allen Marlow, Saline, MI (US); Bernard A. Meyer, Taylor, MI (US); Lakhi N. Goenka, Ann Arbor, MI (US); Harvinder Singh, Shelby Twp, MI (US)

Correspondence Address: BRINKS HOFER GILSON & LIONE, P.O. BOX 10395, CHICAGO, IL, 60610, US

(21) Appl. No.: 10/270,994

(22) Filed: Oct. 15, 2002

Related U.S. Application Data
(60) Provisional application No. 60/330,306, filed on Oct. 19, 2001.

(51) Int. Cl. H04R 3/00; H03G 3/20; G10L 11/00

(52) U.S. Cl. 381/110; 367/198; 704/275

(57) ABSTRACT

A voice-activated control system in which a voice command transmitted to an audio signal receiver such as a microphone is digitized by a voice recognition program that produces an address and a function corresponding to the component to which the voice command is directed. The digitized signal is converted by an IR transceiver or an encoder/decoder to an IR signal, which is transmitted via an LCC bus to one or more devices attached to it. The device that has the appropriate address is actuated to perform the function and/or provide feedback to the system. The invention also includes voice-activated systems that rely on a centralized control approach while a third type of system uses a hybrid system that uses both lcc-based and electrical-based input. The present invention is also directed to various methods of activating and controlling one or more components of a system through a voice-activated system.

This application claims the benefit of a U.S. Provisional Application No. 60/330,306 filed on Oct. 19, 2001, the entirety of which is incorporated herein.

### FIELD OF THE INVENTION

The present invention relates to a system and method for activating and controlling one or more components of a system. In particular, the invention relates to a system and method for activating and controlling one or more components of a system using a light communication channel.

### BACKGROUND OF THE INVENTION

Electronic components are commonly mounted on the surface of conventional molded three-dimensional substrates. Presently, communications between the components on such a substrate occur mainly through the use of hole drillings, electrical wirings, and other conventional connectors. However, reliance on conventional connection techniques creates various disadvantages such as added complexity in component assembly, inconsistent connector reliability due to the large number of required wirings, signal interference and cross-talking between adjacent wires, increase in the weight of the substrate, and high production cost.

### BRIEF SUMMARY OF THE INVENTION

The light communication channel (LCC)-based voice-activated control system of the present invention can be accomplished in various ways. One approach is to use a decentralized control strategy. In this approach, a voice command transmitted through an audio signal receiver such as a microphone is digitized by a voice recognition software that produces an address and a function corresponding to the voice command. The digitized signal is then converted by an IR transceiver or an encoder/decoder (endec) to an IR signal, which is transmitted via the LCC bus to devices attached to it. The device having the appropriate address is then actuated to perform the function and/or provide feedback to the system. Each device preferably has an IR transceiver. Additional microphones may be connected to the main voice software module using electrical wiring.

A second approach uses a centralized control strategy. In this approach, the signal from the microphone is amplified and converted via an LED to an analog IR/light signal. This is then routed to a LCC bus to a master control unit or master controller, which contains a voice recognition software and commands. The master controller then sends out IR signals to the LCC bus to actuate various devices attached to the bus. Numerous microphones may be added to the system merely by having them communicate with the mail LCC bus using their corresponding analog IR converter.

A third approach uses a hybrid system. In this system, the master controller has the ability to process either an LCC-based or an electrical-based input, thereby allowing the use of both conventional as well as LCC-based technology.

In one aspect of the invention, a voice-activated control system is provided that comprises an audio signal receiver that receives an audio input. A voice recognition program is used to digitize the audio input and assign an address and a function corresponding to a component to which the audio input is directed. A first signal converter converts the digitized audio input to a light signal. An LCC bus then receives the light signal and directs the light signal to a second signal converter to which is operatively connected at least one device. A signal from the second signal converter actuates the at least one device to perform the function that corresponds to the audio input. The LCC bus also comprises at least one surface signal router such as a reflective coating. The first signal converter or second signal converter can be a transceiver or an encoder/decoder.

In another aspect, a voice-activated control system is provided that comprises an audio signal receiver that receives an audio input, a signal converter that converts the audio input to a light signal, and a first LCC bus that receives the light signal generated by the signal converter. A master control unit receives the light signal from the first LCC bus and contains a voice recognition software. The master control unit then sends out a light signal to a second LCC bus to actuate at least one device connected to the second LCC bus. The master control unit can be used to process either an LCC-based input or an electrical-based input. The LCC bus may include at least one surface signal router which can be a reflective coating. The signal converter can be an LED or a laser diode.

In another aspect of the invention, a voice-activated control system is provided comprising an audio signal receiver that receives an audio input, a signal converter that converts the audio input to a light signal, and a voice recognition unit that digitizes the audio input, assigns an address and a function that correspond to the audio input, and generates an output signal. The output signal propagates through an LCC matrix that has at least one surface signal router, on the LCC matrix for controlling the direction of propagation of the output signal from the voice recognition unit. The output signal from the voice recognition unit then actuates at least one component embedded in the LCC matrix.

In another aspect, a voice-activated control system is provided comprising an LCC matrix through which a signal propagates, at least one surface signal router that controls the direction of propagation of a signal within the LCC matrix, and an audio signal receiver that receives an audio input. A voice recognition unit digitizes the audio input, assigns an address and a function that correspond to the audio input, and generates a first signal corresponding to the audio input. At least one signal converter converts the first signal into a second signal, and at least one component embedded in the LCC matrix is activated by the second signal that corresponds to the audio input.

The present invention also provides various methods for controlling a component of a system. In one aspect, a method is provided that comprises sending an audio input to an audio signal receiver, digitizing the audio input using a voice recognition software to generate a digitized audio signal, and assigning a component address and a component function that correspond to the component to which the audio signal is directed. The digitized audio input is then converted to a light signal using a first signal converter and the light signal is directed to an LCC bus. Following this step, the light signal is transmitted through the LCC bus to a second signal converter that converts the light signal to an output signal. The output signal is then directed to a device that is operatively connected to the second signal converter. The device is actuated via the output signal to perform a function that corresponds to the audio input.

In another aspect, a method for controlling a component of a system is provided comprising sending an audio input to an audio signal receiver, converting the audio input to a light signal using a first signal converter, and then directing the light signal through the LCC bus to a master control unit that contains a voice recognition program and that generates an output signal. The output signal is then directed from the master control unit to a second LCC bus to actuate at least one device that is operatively connected to the second LCC bus.

In still another aspect of the invention, a method for controlling a component of a system is provided that comprises sending an audio input to an audio signal receiver and directing the audio input to a voice recognition unit. The voice recognition unit digitizes the audio input, assigns an address and a function that correspond to the component to which the audio input is directed, and generates an output signal. The output signal is then directed to a first signal converter that converts the output signal to a light signal. This step is followed by the steps involving transmitting the light signal to an LCC matrix that comprises a surface signal router and directing the light signal to a second signal converter that converts the light signal to an electrical signal. The electrical signal is then transmitted to at least one component embedded in the LCC matrix.

### BRIEF DESCRIPTION OF SEVERAL VIEWS OF THE DRAWINGS

FIG. 1a shows a schematic diagram depicting a voice activation system based on a decentralized control approach.

FIG. 1b shows a schematic diagram depicting a system similar to that shown in FIG. 1a but with multiple microphones made available for sending voice signals.

FIG. 2 illustrates another aspect of the invention based on a centralized control approach.

FIG. 3 is a detailed version of FIG. 1a which illustrates a voice-activated control system based on a decentralized control approach.

FIG. 4 is a detailed version of FIG. 2 which illustrates a voice-activated control system based on a centralized control approach.

FIG. 5 is a side view of a portion of a voice-activated control system.

FIG. 6 is a configuration similar to that shown in FIG. 5 except that the IR transceivers are connected to traces or signal conduction channels (which can be a flatwire) using electrically-conducting joints.

FIG. 7 shows an LCC matrix configured for use in an IR-based communication system.

### DETAILED DESCRIPTION OF THE INVENTION

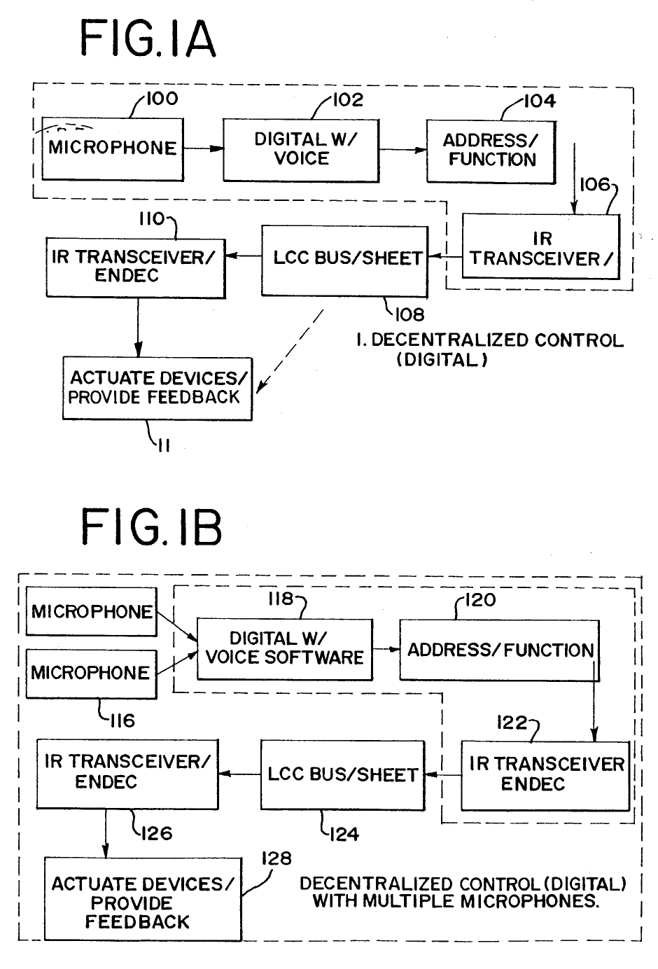

Various configurations or implementations of the voice-activated system of the invention are possible. In one aspect, a voice activation system is based on a decentralized control approach. This configuration is illustrated in FIG. 1a. In this configuration, the audio signal received by the microphone 100 is digitized by a voice recognition software 102 that then produces an address and a function 104 that correspond to the voice command. The digitized audio signal is then converted by a signal converter, such as a transceiver or an encoder/decoder (endec) 106, to a light signal such as an IR signal. The light signal can then be transmitted via the LCC bus 108 to a device 112 attached to it. The device 112 that has the appropriate address is then actuated to perform the desired function and/or provide feedback to the system. Preferably, each device has a signal converter operatively connected to it. Additional microphones may be connected to the main voice software module using electrical connectors. More than one device may be connected, directly or indirectly, to the voice recognition system. As shown by the dashed arrow in FIG. 1a, a light signal can be transmitted directly from the LCC bus/sheet to the devices. FIG. 1b shows a system similar to that shown in FIG. 1a except that here multiple microphones are made available for sending voice signals.

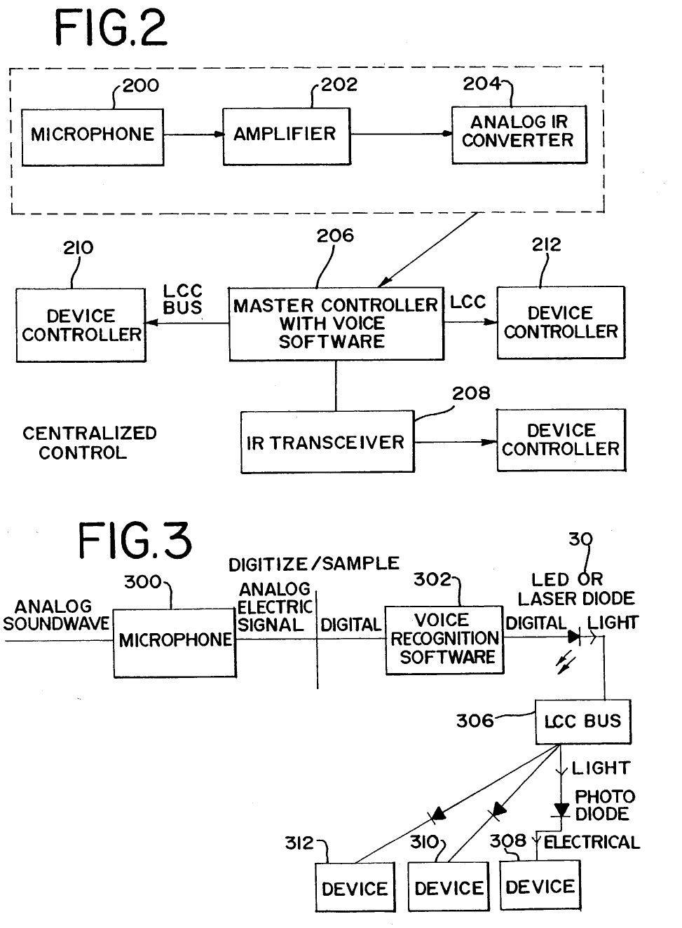

FIG. 2 illustrates another aspect of the invention based on a centralized control approach. In this case, the audio signal from the microphone 200 is amplified using an amplifier 202 and converted to an IR signal using an analog IR converter 204. The IR signal is then routed through a first LCC bus to a master control unit or master controller 206 that contains voice software and commands. The master controller 206 then sends out IR signals through at least one other LCC bus to actuate at least one device attached to the bus. As in FIG. 1b, more than one microphone may be added to the system simply by having them communicate with the main LCC bus using an analog IR converter.

FIG. 3 is a diagram that provides a detailed illustration of a voice-activated control system based on a decentralized control approach. In this configuration, the microphone 300 receives a voice command that is digitized by a voice recognition software 302. The voice recognition software 302 then generates an address and a function for a given digital output signal that corresponds to the voice command. The output signal produced by the voice recognition software 302 is then converted by an IR transceiver/endec 304 to an IR or light signal, which is transmitted via the LCC bus 306 to devices 308, 310, 312 attached to it. The device with a matching address is then actuated to perform the function and/or provide feedback to the system. Typically, each device has a corresponding IR transceiver. Additional microphones may be connected to the main voice software module using connectors such as electrical wirings.

Once an address and function is assigned to the digital signal, it propagates from the voice recognition software 302 to the emitter 304, which transmits the signal to the LCC bus 306. In one aspect, the emitter 304 is a visible light generation device such as a light emitting diode (LED) or a laser diode. If desired, more than one emitter or more than one type of emitter may be used.

The signal from the emitter 304 propagates to the LCC bus 306 and is received by a receiver 308. The receiver 308 is preferably an electromagnetic radiation receiving or collection device such as a photodiode. The receiver 308 receives or collects one or more signals from the signal diffusion substrate 306. The receiver 308 provides an output signal to devices 310, 312, 314, wherein the output signal has an address and function assigned to it in response to the voice command input to the microphone 300. The receiver 308 may have a frequency specific filter to reduce or eliminate interference from signals with different frequencies. The components 310, 312, 314 can be, for example, any devices, such as a clock, interior or exterior lights, an audio system, mirrors, seat and window controls or any other device that may be used within a vehicle. In a typical configuration, the number of receivers used corresponds to the number of components in the system.

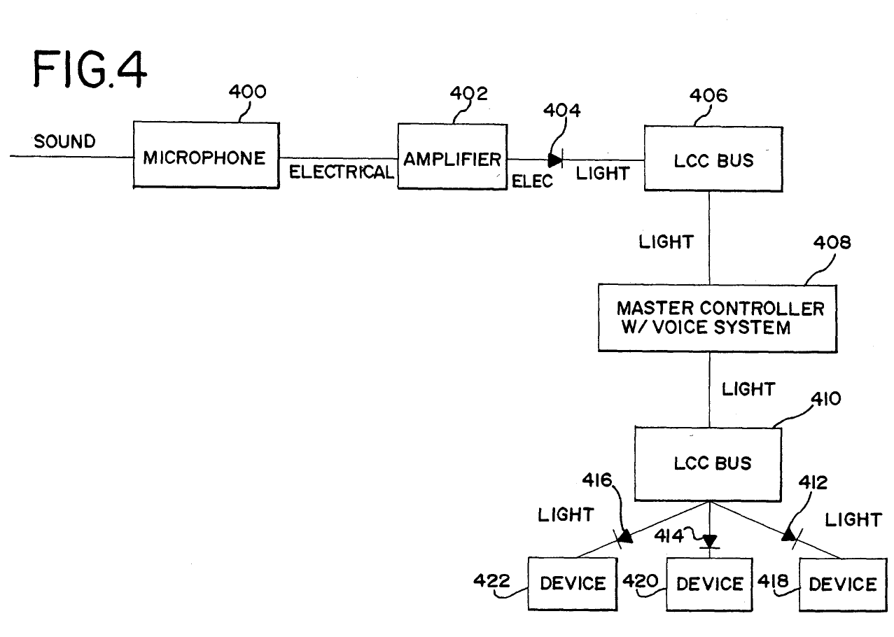

FIG. 4 is a diagram that provides a detailed illustration of a voice-activated control system based on a centralized control approach. In this aspect, the microphone 400 receives a voice command that is amplified using an amplifier 402 and converted via an LED to an analog IR signal using an analog IR converter 404. The IR signal is then routed to an LCC bus 406 to a master control unit or master controller 408, which also contains the voice software and commands. The master controller then sends out IR signals to the LCC bus 410 which actuate the devices attached to the LCC bus 410. Additional microphones may be added to the system simply by having them communicate with the main LCC bus using one or more analog IR converters.

In another aspect of the invention, a hybrid system that incorporates both an LCC and conventional connectors is used. In this system, the master controller is used to process either an LCC-based or an electrical-based input. This allows the use of both conventional as well as LCC-based technology. LCC-based technology allows the attachment of LCC components directly on the LCC bus or sheet as necessary without the need for specialized connectors.

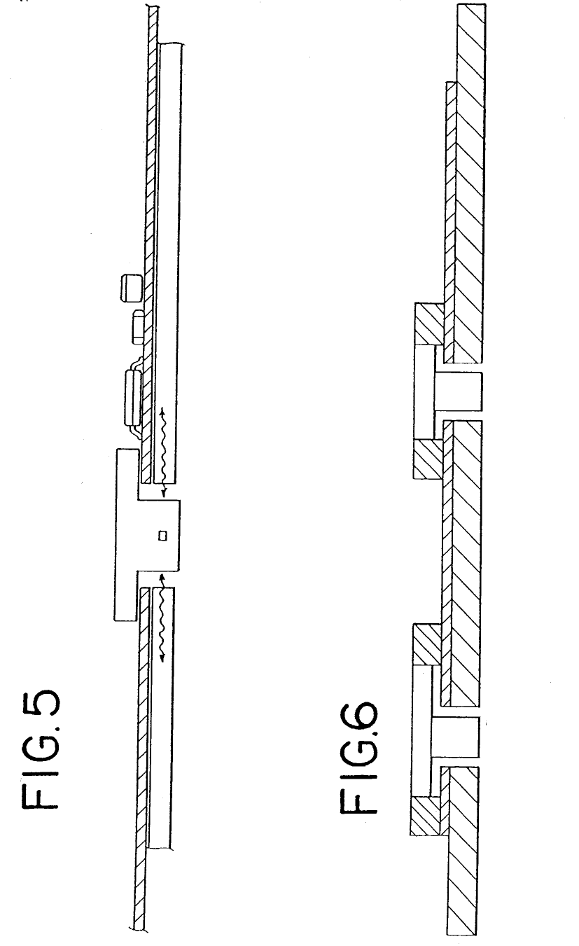

FIG. 5 is a side view of a portion of a voice activation/control system. In this aspect, a signal conduction medium such as a flatwire is placed on top of an LCC substrate. One or more electronic, optical, or opto-electronic components are assembled on the flatwire surface. FIG. 5 shows an IR transceiver that flanks two LCC-based channels, which can have a rectangular, square, or other shapes. Using an IR transceiver, an IR signal propagating towards the IR transceiver is converted into an electrical signal that can then be transmitted to at least one of the components on the surface of a signal conduction channel (here shown as a flatwire). Conversely, an electrical signal from any one of the components on the surface of the signal conduction channel can be converted into a light signal by the IR transceiver, which can then propagate through the LCC channel towards at least one target signal receiver or signal router in another portion of the same or different system or component.

FIG. 6 is a configuration similar to that shown in FIG. 5. In this configuration, the IR transceivers are connected to traces or signal conduction channels (which can be a flatwire) via electrically-conducting joints.

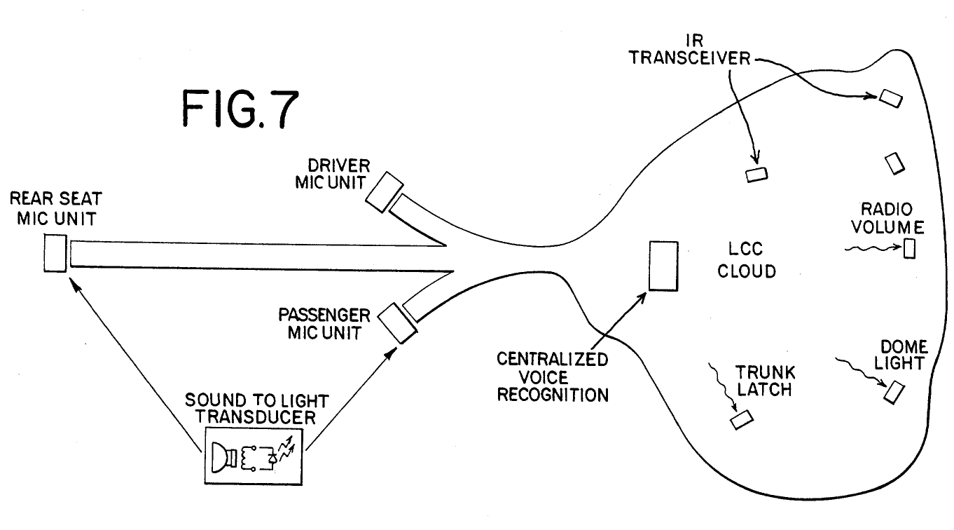

FIG. 7 shows an LCC matrix configured for use in an IR-based communication system. In this aspect, various components such as a radio, television, or video system, trunk latch, and dome lights are embedded in an LCC matrix. For example, components such as radio volume control, dome light, and trunk latch may connected via the LCC to a centralized voice recognition system. In this configuration, at least three microphones, e.g., driver, passenger, and rear seat microphones, are used for receiving voice commands for activating various functions of the components such as volume or temperature adjustment. The LCC material is preferably coated with a reflective material to allow a signal to be transmitted from a signal source to a target signal receiver. When propagating from a signal source to a target signal receiver, a signal may undergo multiple internal reflections. A substantial portion of the LCC may be coated with a reflective material except on surfaces where electrical, optical, or optoelectronic components are to be placed. In another aspect, only certain areas of the LCC surface are coated with at least one type of reflective material depending on the number and types of components to be assembled on the LCC surface.

The LCC may also be formed such that a signal such as an IR signal can be directed from a single source to one or more signal receivers. For example, indentations, pressure fit structures, or inclined, oblique, or wedge-shaped surface cuts can be formed on the LCC to assist or facilitate signal transmission from a signal source to one or more target signal receivers. The surface cuts may assume various shapes including wavy, curvilinear, zig-zag, as well as various irregular shapes.

In an aspect of the invention, the control and activation system includes a speech processor, which could be any microprocessor, and memory which can be any suitable electronic storage device. Preferably, the speech processor includes a microcomputer that has a main processor, an audio processor, multiplex interfaces, operating system software, and application software. An audio processor is typically used to digitize spoken sounds from the microphone while a voice application software is used to analyze the digitized speech to determine the presence of a matching voice command.

Preferably, in the memory is stored software programming that provides multiple distinct speech engines suitable for performing the method of the invention. The voice commands may include key words that identify a parameter to be adjusted such as air flow, temperature, speed, window and seat positions, and radio and/or video volume. A voice command may also be selected from a preset menu of commands. Typically, a speech processor analyzes the digitized speech signals using speech recognition algorithms to allow identification of a command contained in a grammar set. The microphones and push buttons can be provided in convenient locations inside, for example, a vehicle to allow detection by the system of the voice command's source. For example, the push buttons may be mounted to the arm rests, steering wheel, or to the instrument display panel. A user interface that provides either audio or visual output, or both, such as an LCD display unit may be connected to the microphones through a microphone interface. An input/output module, which allows the transmission of data to the vehicle accessories or components and therefore enables the control of the various function parameters associated with each accessory or component, is preferably connected to the vehicle components or accessories through a network bus.

Any number of microphones can be used in the various aspects of the invention. Using means known in the art, a voice command received by a microphone is typically converted to an analog signal in the form of an electrical current. The analog signal is then received by the voice recognition software, which is operatively connected to the microphone. At least one voice recognition software is used for the one or more microphones used in an implementation of the invention. A voice recognition software generally includes a speech processor and memory that provide multiple, unique speech engines suitable for recognizing and processing voice commands to actuate, for example, various accessories or components in a vehicle. The analog signal is digitally sampled such that the voice recognition software can assign an address and function corresponding to a component that is to be actuated according to the command received by the microphone.

Some of the vehicle components or accessories that can be controlled or activated are clocks, door locks, seat and window controls, navigation system, climate control, interior or exterior lights and audio system.

A signal conduction matrix or an LCC, otherwise known as light communication channel, is a structure made of at least one type of light-transmissive material formed into any shape that would allow transmission of a signal in the form of light from one point to another. An LCC is described in more detail below, but one of its characteristics is that it can be used as a substrate such as an optical substrate that can be formed into various shapes such as a rectangular slab or the shape of a part or the entirety of, for example, a main frame of an instrument panel display. As such, it can be used as a primary or secondary transmission means for a signal, such as an optical signal propagating from at least one signal source to at least one signal receiver, or it may encompass various electronic and/or optical components to allow a signal such as an optical signal to be directed to various electronic and/or optical components within the substrate, without having to resort to the use of conventional signal focusing means such as a beam splitter or focusing lens. An LCC may also assume other shapes such as a ring, strand, sheet, or ribbon.

Structures that comprise an LCC include an LCC in the form of strands or other structural shapes. Structures that comprise an LCC also include an LCC connected or fabricated with one or more components or systems such as a detector, light source, or an electronic system.

Preferably, the LCC comprises a polymeric material. The material comprising the LCC may be polybutylene terephthalate, polyethylene terephthalate, polypropylene, polyethylene, polyisobutylene, polyacrylonitrile, poly(vinyl chloride), poly(methyl methacrylate), silica, or polycarbonate. Preferably, the polymeric material is a photorefractive polymer.

The polymeric material that forms the LCC may be connected to or manufactured as part of engine structures such as intake manifolds. Information obtained from the signal receivers that relates to monitored parameters can then be routed through the LCC to at least one electronic system such as a process control system.

Preferably, the LCC material is made of at least one material that allows the transmission of light of various frequencies. Thus, for example, the LCC may comprise a first material transparent or translucent to a first frequency of the signals and a second material that is transparent or translucent to a second frequency of the signals.

The LCC can have various configurations. Thus, the LCC may be flat, curvilinear, wavy, or asymmetrical. The LCC may also have various dimensions including non-uniform thickness, diameter, width, and length. The LCC may be fabricated using a moldable material so that the LCC can be cast and then cured to a desired shape. The LCC may have sections or areas that are connected, molded, or pressed onto a surface of a circuit board. In one aspect, the LCC is integrated with structures such as printed circuit boards, flexible substrates, flatwire, and MID circuits.

The LCC preferably has a reflective coating on at least one of its surfaces. In one aspect of the invention, the reflective coating covers the entire surface or substantially the entire surface of the except for the portions of the surface where the signal source and signal receivers are operatively connected to the LCC. The reflective coating may be used to, for example, cover only the surface of the LCC that substantially encompass a volume of the LCC through which the signal source is transmitted to the signal receivers. The entire LCC may be coated with a reflective material.

The reflective coating can be made of any material that reflects the signal transmitted through the LCC. The reflective coating can also be made of at least one metal or metallic alloy containing metals such as aluminum, copper, silver, or gold.

A surface signal router can be a reflective coating on the surface of the LCC. The surface signal router directs a signal from the signal source to one or more target signal recipients, such as a photodetector or an IR analyzer, that are positioned at various points on the surface of the LCC. Surface signal routers in the form of reflective coatings can be strategically distributed throughout the various areas or sections of the surface of the LCC depending on factors such as the number and type of components that form part of a signal conduction network. They can also assume the form of inclined, oblique, or wedge-shaped cuts on the surface of the 3-D LCC. As used herein, an “inclined” cut includes cuts having an angular shape relative to a surface of the LCC; this includes oblique and wedge-shaped cuts. Routers in the form of surface cuts with other shapes such as zig-zag, wavy, or combinations of various shapes may also be used. Preferably, these surface cuts are coated with at least one reflective material such as a metal or metal alloy. In one aspect, a combination of reflective coatings and surface cuts with reflective coatings is used to enable a signal to propagate through the LCC via, for example, multiple internal reflections.

Power sources that produce energies corresponding to different wavelengths may be used to power different signal receivers that have photoreceptors sensitive to certain wavelengths. Further narrowing of a wavelength range may be performed using at least one optic element such as bandpass filter.

Data obtained from the signal receivers may be transmitted through a main communication bus to an electronic system, such as an electronic controller, for further data processing. The data may be transmitted using a light signal, such as an IR signal. A power distribution system may also be included in an instrument panel, on-engine system, or other devices that require power distribution to the signal receivers.

A signal may be directed to any or various directions within the LCC, unless, for example, the signal source or another component blocks the signal. The signals may propagate, sequentially or simultaneously, along the same or opposite directions. The signal receivers may be positioned in any suitable location on a surface of the LCC where the signal receivers can receive a signal from at least one signal source. Multiple signal receivers may receive signals from a single signal source.

Signals such as optical signals from optoelectronic transmitters can be channeled or transmitted through air if there are no obstacles in their path. The transmitters preferably generate a light signal with a unique wavelength. In an aspect of the invention, a wavelength selective filter is placed in front of the signal receiver so that little or no interference occurs between different transmitters and signal receivers.

The signal source can be a light source. An example of a preferred light source is an infrared light source. However, the signals can have any electromagnetic frequency capable of transmission through the LCC and communication between the signal source and the signal receivers. The signal being transmitted may be a combination of electromagnetic frequencies. The signal source includes, but is not limited to, an LED, a laser, or an RF source. The laser may emit IR, visible, or ultraviolet light.

The signal source is preferably an electromagnetic radiation generation device. Preferably, each signal source is a light generation device such as a laser or a light emitting diode (LED). Alternatively, each signal source is a radio frequency (RF) generation device such as an RF transmitter. For example, a first signal source may be an electromagnetic radiation generation device such as a LED or a laser and a second signal source may be an RF transmitter.

A signal source and at least one signal receiver is preferably integrated with a component such as an IR or RF transceiver, which may transmit a first signal at a given time and receive a second signal at another time. The first and second signals may have the same or different frequencies. The signal receiver may include both a detector and another component such as a capacitor where the collected energy may be stored.

As used herein, a signal receiver refers to a device that receives a signal from a given source. The signal received by a signal receiver is typically a light signal. Thus, a signal receiver may include at least one component such as a photodetector or both a photodetector and a capacitor. In particular, at least one of the signal receivers may include an electromagnetic radiation reception or collection device such as a photodiode or an RF sensor. The signal receivers include, but are not limited to, photodiodes, microchannel plates, photomultiplier tubes, or a combination of signal receivers. The signal receivers may receive or collect at least one signal through the LCC. In one aspect of the invention, the signal receivers provide an output signal to an electronic system in response to a signal that propagates through the LCC. The signal receivers preferably have at least one frequency specific filters to reduce or eliminate interference from signals with certain frequencies or frequency ranges. In one aspect, the signal receivers are embedded within the LCC or attached to it. In one aspect of the invention, an emitted signal or energy from the central signal source may be directed to the signal receivers using a routing means such as a prism, lens, or mirror through the LCC.

Various embodiments of the invention have been described and illustrated. However, the description and illustrations are by way of example only. Other embodiments and implementations are possible within the scope of this invention and will be apparent to those of ordinary skill in the art. Therefore, the invention is not limited to the specific details, representative embodiments, and illustrated examples in this description. Accordingly, the invention is not to be restricted except in light as necessitated by the accompanying claims and their equivalents.

1. A voice-activated control system comprising:
an audio signal receiver that receives an audio input,
a voice recognition software that digitizes the audio input to produce a digitized audio input and assigns an address and a function corresponding to a component to which the audio input is directed,
a first signal converter that converts the digitized audio input to a light signal,
an LCC bus that receives the light signal and directs the light signal to a second signal converter, and
at least one device connected to the second signal converter,
wherein a signal from the second signal converter actuates the at least one device to perform the function required by the audio input.

2. The voice-activated control system of claim 1, wherein the LCC bus comprises a material selected from a group consisting of polybutylene terephthalate, polyethylene terephthalate, polypropylene, polyethylene, polyisobutylene, polyacrylonitrile, poly(vinyl chloride), poly(methyl methacrylate), silica, and polycarbonate.

3. The voice-activated control system of claim 1, wherein the LCC bus comprises at least one surface signal router.

4. The voice-activated control system of claim 3, wherein the surface signal router is a reflective coating.

5. The voice-activated control system of claim 1, wherein the first signal converter or second signal converter is a transceiver or an encoder/decoder.

6. A voice-activated control system comprising:
an audio signal receiver that receives an audio input,
a signal converter that converts the audio input to a light signal,
a first LCC bus that receives the light signal generated by the signal converter, and
a master control unit that receives a light signal from the first LCC bus and contains a voice recognition program,
wherein the master control unit sends out a light signal to a second LCC bus to actuate at least one device connected to the second LCC bus.

7. The voice-activated control system of claim 6, wherein the LCC bus comprises a material selected from a group consisting of polybutylene terephthalate, polyethylene terephthalate, polypropylene, polyethylene, polyisobutylene, polyacrylonitrile, poly(vinyl chloride), poly(methyl methacrylate), silica, and polycarbonate.

8. The voice-activated control system of claim 6, wherein the LCC bus comprises at least one surface signal router.

9. The voice-activated control system of claim 8, wherein the surface signal router is a reflective coating.

10. The voice-activated control system of claim 6, wherein the signal converter is an LED or a laser diode.

11. The voice-activated control system of claim 6, wherein the master control unit processes an LCC-based input and an electrical-based input.

12. A voice-activated control system comprising:
an audio signal receiver that receives an audio input,
a signal converter that converts the audio input to a light signal,
a voice recognition unit that digitizes the audio input, assigns an address and a function that correspond to the component to which the audio input is directed, and generates an output signal,
an LCC matrix through which the output signal propagates,
at least one surface signal router on the LCC matrix that controls the direction of propagation of the output signal from the voice recognition unit, and
at least one component embedded in the LCC matrix that is activated by the output signal from the voice recognition unit.

13. A voice-activated control system comprising:
an LCC matrix through which a signal propagates,
at least one surface signal router that controls the direction of propagation of a signal within the LCC matrix,
an audio signal receiver that receives an audio input,
a voice recognition unit that digitizes the audio input, assigns an address and a function that correspond to a component to which the audio input is directed, and generates a first signal corresponding to the audio input,
at least one signal converter that converts the first signal into a second signal, and
at least one component embedded in the LCC matrix that is activated by the second signal that corresponds to the audio input.

14. The voice-activated control system of claim 13, wherein the LCC matrix comprises an electrically-conductive material.

15. The voice-activated control system of claim 14 further comprising at least one component that is operatively connected on the surface of the electrically-conductive material.

16. The voice-activated control system of claim 14, wherein the electrically-conductive material is formed as a layer on one side of the LCC matrix.

17. The voice-activated control system of claim 14, wherein the electrically-conductive layer is operatively connected to another electrically-conductive layer by electrically-conductive connectors that are operatively connected to a transceiver.

18. A method for controlling a component of a system comprising:
sending an audio input to an audio signal receiver,
digitizing the audio input using a voice recognition program to generate a digitized audio input,
assigning a component address and a component function that correspond to a component to which an audio input is directed,
converting the digitized audio input to a light signal using a first signal converter,
transmitting the light signal through an LCC bus to a second signal converter that converts the light signal to an output signal,
directing the output signal from the second signal converter to a device that is operatively connected to the second signal converter, and
actuating the device via the output signal to perform a function required by the audio input.

19. A method for controlling a component of a system comprising:
sending an audio input to an audio signal receiver,
converting the audio input to a light signal using a first signal converter,
transmitting the light signal through a first LCC bus to a master control unit that contains a voice recognition program and that generates an output signal, and
directing the output signal from the master control unit to a second LCC bus to actuate at least one device that is operatively connected to the second LCC bus.

20. A voice-activated control system comprising:
sending an audio input to an audio signal receiver,
directing the audio input to a voice recognition unit that digitizes the audio input, assigns an address and a function that correspond to a component to which the audio input is directed, and generates an output signal,
directing the output signal to a first signal converter that converts the output signal to a light signal,
transmitting the light signal to an LCC matrix that comprises a surface signal router,
directing the light signal propagating through the LCC matrix to a second signal converter that converts the light signal to an electrical signal, and
transmitting the electrical signal to at least one component embedded in the LCC matrix.
